(19) United States
(12) Patent Application Publication
(10) Pub. No.: US 2026/0090016 A1
(43) Pub. Date: Mar. 26, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yu-Ho CHIANG, Hsinchu (TW); Jiun-Jie Chao, Miaoli County (TW); Jyh-Huei Chen, Hsinchu City (TW); Jye-Yen Cheng, Taichung (TW)

(73) Assignee: Taiwan Semiconductor Manufacturing Company, Ltd., Hsinchu (TW)

(21) Appl. No.: 18/894,007

(22) Filed: Sep. 24, 2024

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121

(57) ABSTRACT

A semiconductor device includes a semiconductor substrate including a first side and a second side opposite to each other, semiconductor channel layers disposed over the first side of the semiconductor substrate and vertically separating apart from one another, a gate structure vertically between adjacent two of the semiconductor channel layers, a source/drain (S/D) structure laterally abutting the semiconductor channel layers, a dielectric stack including a dielectric liner connecting the second side of the semiconductor substrate and a dielectric layer overlying the dielectric liner and having a different material than the dielectric liner, and a backside via landing on the S/D structure and laterally surrounded by the dielectric stack.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are schematic cross-sectional views schematically illustrating various stages of a manufacturing method of a front-side portion of a semiconductor device, in accordance with some embodiments.

FIG. 7 is a schematic plan view of a portion of the semiconductor device, in accordance with some embodiments.

FIGS. 8, 10, 12, 14, 16, 18, 20, 22, and 24 are schematic cross-sectional views illustrating various stages of a manufacturing method of a backside portion of a semiconductor device taken along reference line X-X of FIG. 7, in accordance with some embodiments.

FIGS. 9, 11, 13, 15, 17, 19, 21, 23, and 25 are schematic cross-sectional views illustrating various stages of a manufacturing method of a backside portion of a semiconductor device taken along reference line Y-Y of FIG. 7, in accordance with some embodiments.

FIG. 26 is a schematic cross-sectional view illustrating a portion of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the disclosure describe a manufacturing process of a semiconductor device. The nanostructure transistor device (also referred to as a gate-all-around (GAA) transistor device) may include one or more backside via(s) isolated from the gate structures by forming a dielectric stack on the backside of the semiconductor substrate. The dielectric stack includes a dielectric liner serving as a receptacle of the overlying dielectric layer, and the material of the dielectric liner may be selected to have an etch selectivity different from the overlying dielectric layer so that the dielectric liner may protect the underlying semiconductor substrate when forming the via hole for the backside via. In this manner, the embodiments of the present disclosure may improve isolation among the backside via, the semiconductor substrate, and the gate structure, reduces AC penalty in the semiconductor device, and/or reduce contact resistance (Rc). The embodiments are not limited in this context. The semiconductor device may be included in microprocessors, memories, and/or other integrated circuits (IC). Accordingly, it is understood that additional processes may be provided before, during, and after the illustrated method, and that some other processes may only be briefly described herein. Also, the structures illustrated in the drawings are simplified for a better understanding of the concepts of the present disclosure. For example, although the figures illustrate the structure of the semiconductor device, it is understood the semiconductor device may be part of an IC that further includes a number of other devices such as resistors, capacitors, inductors, fuses, etc.

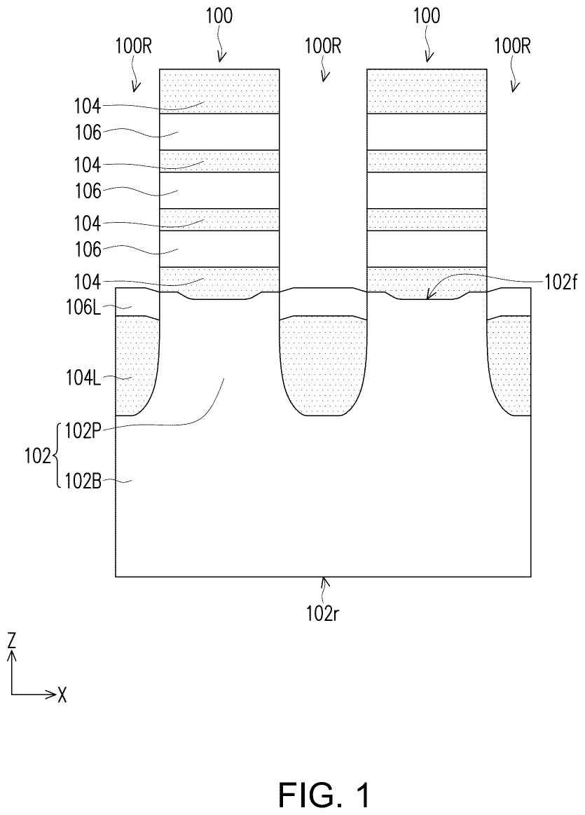

FIGS. 1-6 are schematic cross-sectional views schematically illustrating various stages of a manufacturing method of a front-side portion of a semiconductor device, in accordance with some embodiments. For clarity of illustrations, in the drawings are illustrated the orthogonal axes (X, Y and Z) of the Cartesian coordinate system according to which the views are oriented.

Referring to FIG. 1, fin structures 100 including alternately stacked first semiconductor layers 104 and second semiconductor layers 106 may be formed over a semiconductor substrate 102. In some embodiments, the semiconductor substrate 102 includes a first side (or a front side) 102f and a second side (or a backside) 102r opposite to the first side 102, and the fin structures 100 are formed on the first side 102f of the semiconductor substrate 102. The semiconductor substrate 102 may include a crystalline silicon substrate or a bulk silicon substrate (e.g., wafer). In some embodiments, the semiconductor substrate 102 is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102 includes a SOI substrate. The semiconductor substrate 102 may include various doped regions (not individually shown) doped with p-type or n-type dopants, where the doped regions may be configured for an n-type FET, or alternatively, configured for a p-type FET.

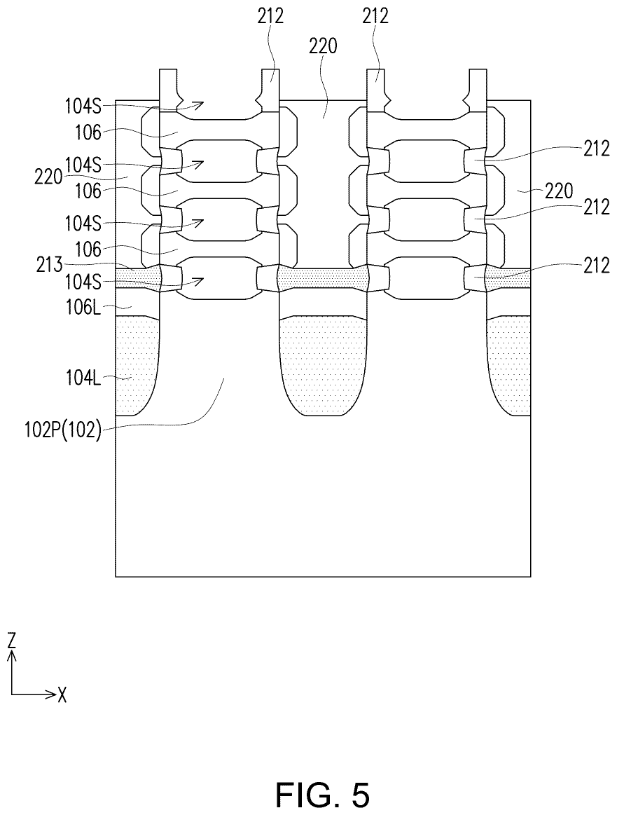

The first semiconductor layers 104 and second semiconductor layers 106 may be alternately stacked to form a stack. The first semiconductor layers 104 may be considered sacrificial layers in the sense that they are removed in the subsequent process (see FIG. 5). In some embodiments, the bottommost one of the first semiconductor layers 104 is formed on the semiconductor substrate 102, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102), and either the first semiconductor layer 104 or the second semiconductor layer 106 may be the topmost layer (or the layer most distanced to the semiconductor substrate 102). The disclosure is not limited by the number of stacked semiconductor layers.

The first semiconductor layers 104 and the second semiconductor layers 106 may have different materials (or compositions) that may provide for different oxidation rates and/or different etch selectivity between the layers. For example, the second semiconductor layers 106 are formed of the same material as the semiconductor substrate 102, while the first semiconductor layers 104 may be formed of a different material which may be selectively removed with respect to the material of the semiconductor substrate 102 and the second semiconductor layers 106. In some embodiments, the material of the first semiconductor layers 104 includes silicon germanium (SiGe). In some embodiments, the second semiconductor layers 106 include silicon (Si), where each of the second semiconductor layers 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets and may be considered as channel layers in the subsequent processes. The terms “semiconductor nanosheets” and “semiconductor channel layers” may be used interchangeably herein.

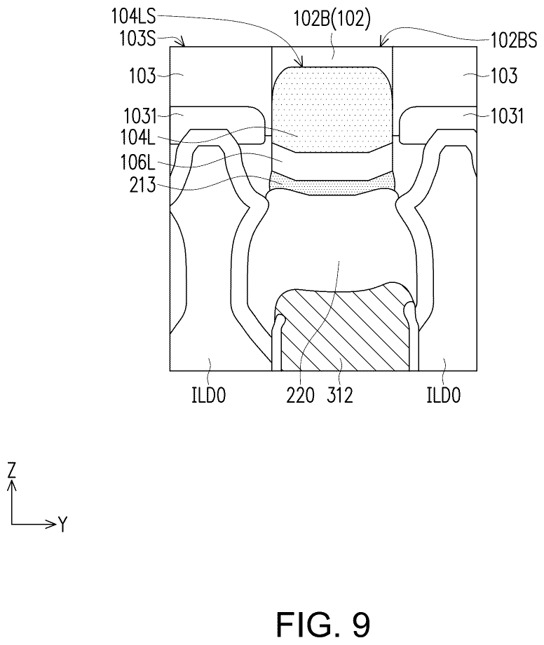

With continued reference to FIG. 1, the stack of the first semiconductor layers 104 and second semiconductor layers 106 may be patterned to form the fin structures 100. The semiconductor substrate 102 may include a base portion 102B and protrusions 102P protruded from the base portion 102B, and each of the fin structures 100 is disposed on one of the protrusions 102P. A plurality of isolation structures (also referred to as shallow trench isolation (STI) structures; not shown in this X-Z cross-section but shown in FIG. 9 and labeled as “103”) may then be formed on the semiconductor substrate 102. Next, a dummy gate structure (not shown) may be formed on the fin structures 100. For example, the dummy gate structure has a lengthwise direction along the X direction which is perpendicular to the lengthwise direction (e.g., the Y direction) of the respective fin structure 100. The dummy gate structure may act to self-align subsequently formed source/drain (S/D) structures, as well as to protect sidewalls of the respective fin structure 100 during subsequent processing. For example, a portion of the respective fin structure 100 directly underlying the dummy gate structure and a portion of the semiconductor substrate 102 underlying the portion of the respective fin structure 100 are removed to form the recesses 100R. The S/D structures will be subsequently formed in the recesses 100R, and the recesses 100R may be referred to as S/D recesses.

Still referring to FIG. 1, a first sacrificial portion 104L and a second sacrificial portion 106L overlying the first sacrificial portion 104L may be formed in the respective recess 100R and may laterally surround the protrusions 102P. The first sacrificial portion 104L may be thicker than the second sacrificial portion 106L, measured along the Z-direction. In some embodiments, the first sacrificial portion 104L and the second sacrificial portion 106L are made of different semiconductor materials (or compositions) that may provide for different oxidation rates and/or different etch selectivity between the layers. For example, the second sacrificial portion 106L is formed of the same material as the semiconductor substrate 102 and/or the second semiconductor layers 106, while the first sacrificial portion 104L is formed of a different material which may be selectively removed with respect to the material of the second sacrificial portion 106L. In some embodiments, the first sacrificial portion 104L is formed of the same material as the first semiconductor layers 104.

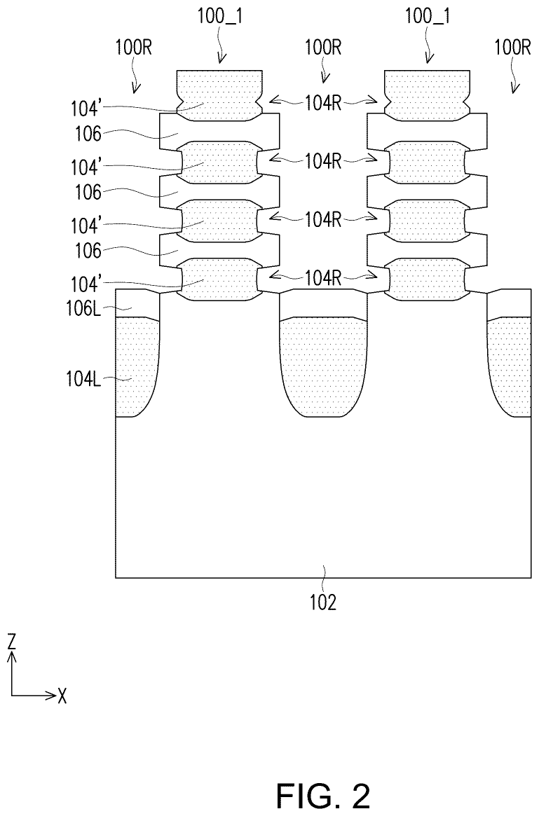

Referring to FIG. 2 and with reference to FIG. 1, portions of the first semiconductor layers 104 exposed by the recesses 100R may be removed in the lateral direction to form a respective etched fin structure 100_1 having etched first semiconductor layers 104′. The respective etched first semiconductor layer 104′ may be laterally recessed from the sidewalls of the underlying (or overlying) second semiconductor layer 106. For example, the etchant of the selective etching process is chosen so that the portions of the first semiconductor layers 104 are removed to form lateral recesses 104R, while the second semiconductor layers 106 may remain substantially intact during the selective etching.

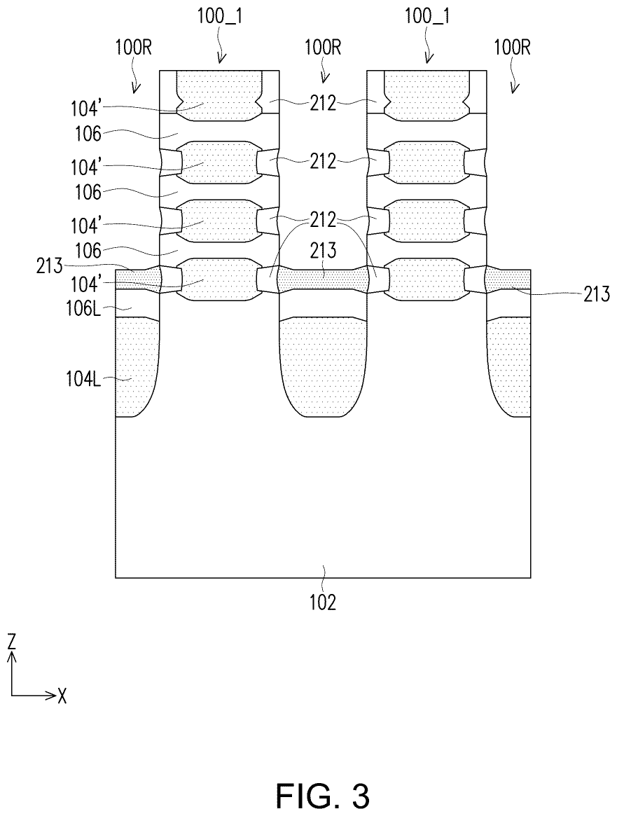

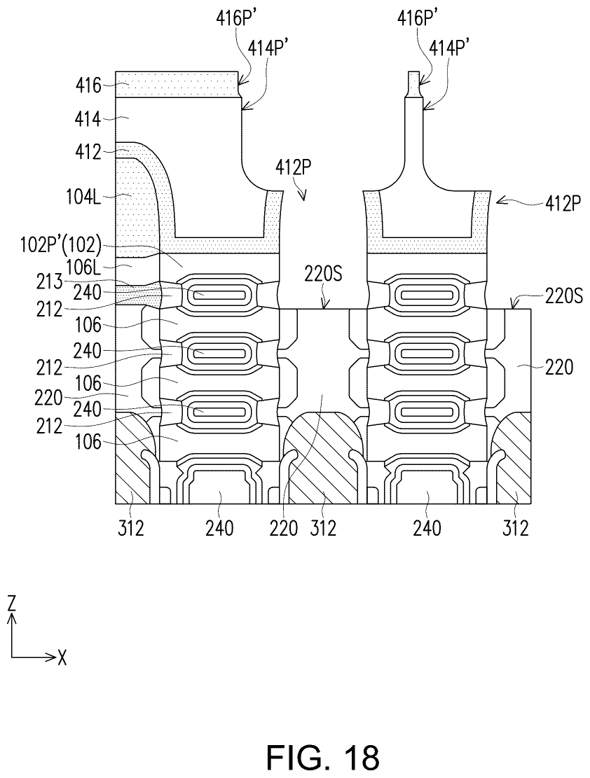

Referring to FIG. 3 and with reference to FIG. 2, inner spacers 212 may be formed in the lateral recesses 104R. For example, the inner spacers 212 are formed along the etched ends of each of the etched first semiconductor layers 104′ and along respective ends (along the Y-direction) of each of the etched first semiconductor layers 104′ and the second semiconductor layers 106. The inner spacers 212 may be formed of silicon nitride, silicon carbon-nitride, silicon-carbon-oxynitride, or any other type of dielectric material, and may be deposited using, e.g., a conformal deposition process followed by etching back process. In some embodiments, a sacrificial isolation layer 213 is formed on the top surface of the second sacrificial portion 106L and alongside the bottommost one of the inner spacers 212. The sacrificial isolation layer 213 may be made of a different material than the inner spacers 212 such that the bottommost one of the inner spacers 212 may remain substantially intact during removing the sacrificial isolation layer 213 in the subsequent process (see FIG. 18). For example, the sacrificial isolation layer 213 includes one or more isolation material(s) such as silicon nitride, silicon carbon-nitride, silicon-carbon-oxynitride, or any other type of isolation materials.

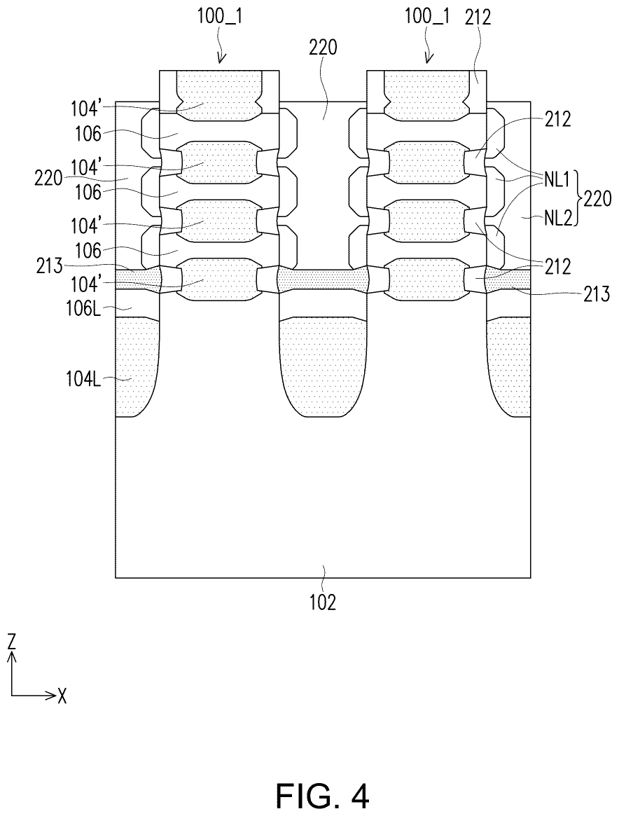

Referring to FIG. 4 and with reference to FIG. 3, epitaxial structures (also called “S/D structures”) 220 may be formed in the recesses 100R and on the sacrificial isolation layer 213. The epitaxial structures 220 may be laterally connected to the exposed surfaces of the second semiconductor layers 106 and the inner spacers 212. The epitaxial structures 220 may each include silicon germanium, indium arsenide, indium gallium arsenide, indium antimonide, germanium arsenide, germanium antimonide, indium aluminum phosphide, indium phosphide, any other suitable material, or combinations thereof. The epitaxial structures 220 may be formed using an epitaxial growth process on the exposed surfaces of each of the second semiconductor layers 106. The material of the epitaxial structures 220 may be doped with a conductive dopant. For example, a strained material is epitaxially grown with an n-type dopant (or a p-type dopant) for straining the epitaxial structures 220 in the n-type region (or the p-type region). That is, the strained material is doped with the n-type dopant (or the p-type dopant) to be the epitaxial structures 220 of the p-type FET (or the n-type FET).

In some embodiments, the material of the epitaxial structures 220 is disposed as a multi-layered structure, with different layers having different degrees of doping. Taking an n-type FET for example, the respective epitaxial structure 220 includes a first layer NL1 and a second layer NL2 on the first layer NL1 and filling the recesses 100R. The first layer NL1 may be grown on the sidewalls of the second semiconductor layers 106 and may (or may not) extend to at least partially cover the sidewalls of the inner spacers 212. The first layer NL1 and the second layer NL2 may have a composition (the elements contained therein and the percentages of the elements) different from the composition of the adjacent layer(s). It should be noted that the epitaxial structures 220 may have other types of configurations, while remaining within the scope of present disclosure.

Referring to FIG. 5 and with reference to FIG. 4, the etched first semiconductor layers 104′ may be removed by etching (e.g., isotropic etching or the like). For example, using etchants which are selective to the materials of the etched first semiconductor layers 104′, while the second semiconductor layers 106 and other components remain relatively un-etched as compared to the etched first semiconductor layers 104′. During the removal process, the epitaxial structures 220 may be protected by the interlayer dielectric (ILD) layer (not shown; shown in FIG. 9 and labeled as “ILD0”) which is formed on the epitaxial structures 220. After the removal of the etched first semiconductor layers 104′, respective bottom and top surfaces of each second semiconductor layers 106 and the top surface of the protrusions 102P of the semiconductor substrate 102 may be exposed by recesses 104S.

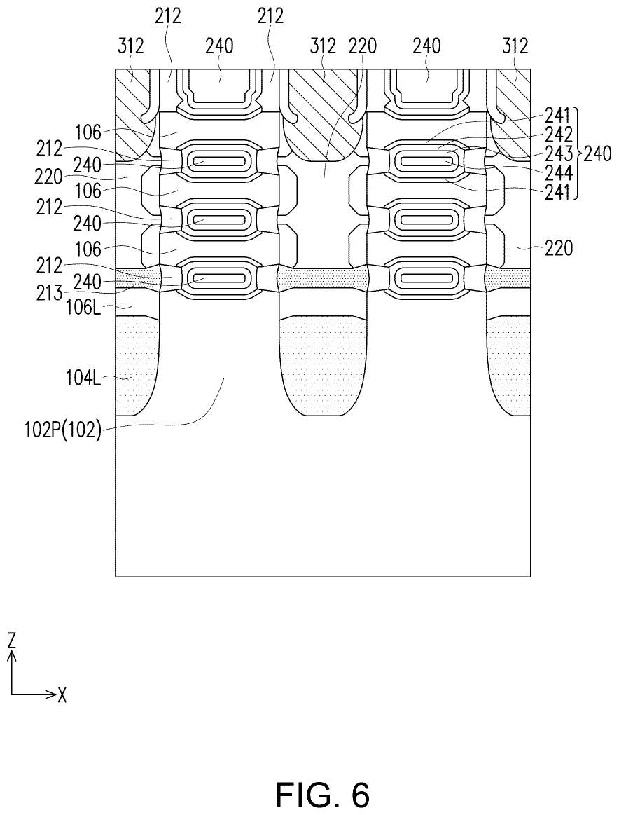

Referring to FIG. 6 and with reference to FIG. 5, a respective gate structure 240 may be formed around the second semiconductor layers 106 and fills the recesses 104S. The second semiconductor layers 106 may function as channel regions. The respective gate structure 240 may include an interfacial layer 241, a gate dielectric layer 242, a work function layer 243, and a gate metal layer 244. For example, the interfacial layer 241 is between each second semiconductor layer 106 and the gate dielectric layer 242 and between the protrusions 102P of the semiconductor substrate 102 and the bottommost gate dielectric layer 242. In the illustrated X-Z cross-section, the interfacial layer 241 may be formed on the top and bottom surfaces of each second semiconductor layer 106 and on the top surface of the protrusions 102P of the semiconductor substrate 102, and then the gate dielectric layer 242 may be formed on the interfacial layer 241 and also formed on the sidewalls of the inner spacers 212. The gate dielectric layer 242 may include high-k dielectric material(s) or other suitable dielectric material(s). The work function layer 243 may be interposed between the gate dielectric layer 242 and the gate metal layer 244, where the work function layer 243 may be formed separately for the n-type FET and the p-type FET which may use different metal layers. The gate metal layer 244 may be formed on the work function layer 243 and fill the rest space of the recesses 104S.

With continued reference to FIG. 6, S/D contacts 312 may be formed on the epitaxial structures 220 and electrically connected to the epitaxial structures 220 (i.e. the S/D structures). A gate contact (not shown) may be formed on the topmost one of the gate structures 240 and may be electrically connected to the gate structures 240. The respective S/D contact 312 and the gate contact may include one or more layers (e.g., liners, barrier layers, diffusion layers, and conductive fill materials). In some embodiments, the top portion of the epitaxial structures 220 is removed when forming the contact holes for the S/D contacts 312, and the epitaxial structures 220 may thus have a concave cured top surface as shown in FIG. 6. The bottom portions of the S/D contacts 312 may be protruded toward the epitaxial structures 220 and in contact with the concave cured top surface of the epitaxial structures 220. It should be noted that the configuration of the S/D contacts 312 shown herein is an example and the S/D contacts 312 may have a different configuration than shown. In addition, the subsequent front-side interconnect process (not shown) may be performed on the S/D contacts 312 and the gate contacts according to the product and circuit design requirements.

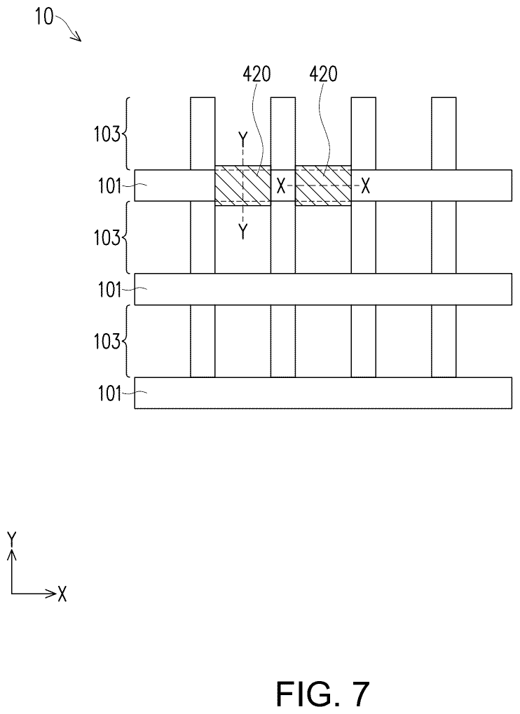

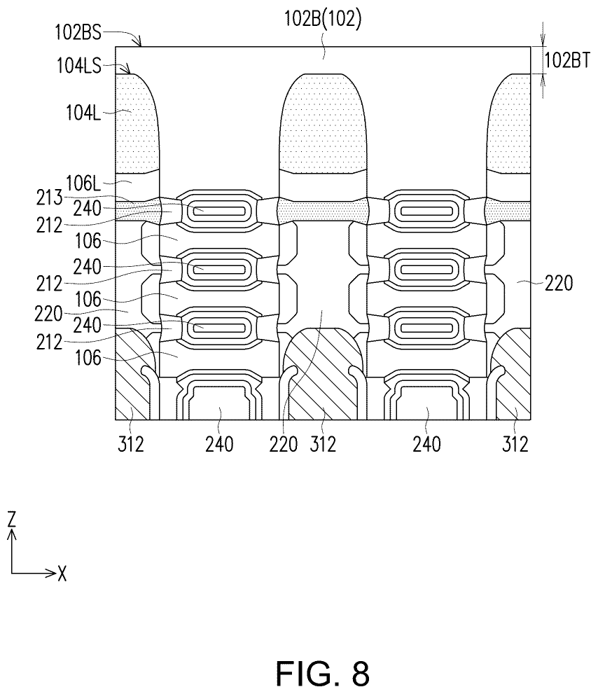

FIG. 7 is a schematic plan view of a portion of the semiconductor device, FIGS. 8, 10, 12, 14, 16, 18, 20, 22, and 24 are schematic cross-sectional views illustrating various stages of a manufacturing method of a backside portion of a semiconductor device taken along reference line X-X of FIG. 7, and FIGS. 9, 11, 13, 15, 17, 19, 21, 23, and 25 are schematic cross-sectional views illustrating various stages of a manufacturing method of a backside portion of a semiconductor device taken along reference line Y-Y of FIG. 7, in accordance with some embodiments. Unless specified otherwise, like reference numerals represent like components in the embodiment shown in FIGS. 1-6.

Referring to FIG. 7, the plan view of a portion (e.g., a backside portion) of a semiconductor device 10 may be provided. For example, the semiconductor device 10 includes an active region 101 which is also referred to as an oxide diffusion or definition (OD). The active region 101 may be a continuous section including one or more fin structures, where the respective fin structure includes alternately stacked semiconductor channel layers and the gate structures. In some embodiments, the active region 101 is electrically isolated from other elements in the semiconductor substrate by one or more isolation structures 103 (e.g., one or more STI structures). One or more backside via(s) 420 may be formed over the backside of the semiconductor substrate and directly over the active region 101 to be in physical and electrical contact with the S/D structures. In the following description, various stages of a manufacturing method of the backside vias in the backside portion of the semiconductor device 10 are described with reference to the following drawings.

Referring to FIGS. 8-9 and with reference to FIG. 6, after the front-side processing is substantially complete, the structure shown in FIG. 6 may be flipped over for backside processing. In some embodiments, a thinning process (e.g., chemical mechanical polishing (CMP), grinding, etching back, combinations thereof, or the like) is performed on the base portion 102B of the semiconductor substrate 102 to reduce the thickness of the semiconductor substrate 102. For example, the base portion 102B of the semiconductor substrate 102 is thinned down to have a thickness 102BT measured between the thinned surface 102BS and the back surface 104LS of the first sacrificial portion 104L. As shown in the Y-Z cross-section, the respective epitaxial structure 220 may be laterally surrounded by the interlayer dielectric (ILD) layer ILD0. The stack of the base portion 102B and the first sacrificial portion 104L may be laterally surrounded by the isolation structures 103. In some embodiments, an isolation hard mask 1031 is disposed between the ILD layer ILD0 and the respective isolation structure 103. After the thinning process, the back surfaces 103S of the isolation structures 103 may be accessibly exposed.

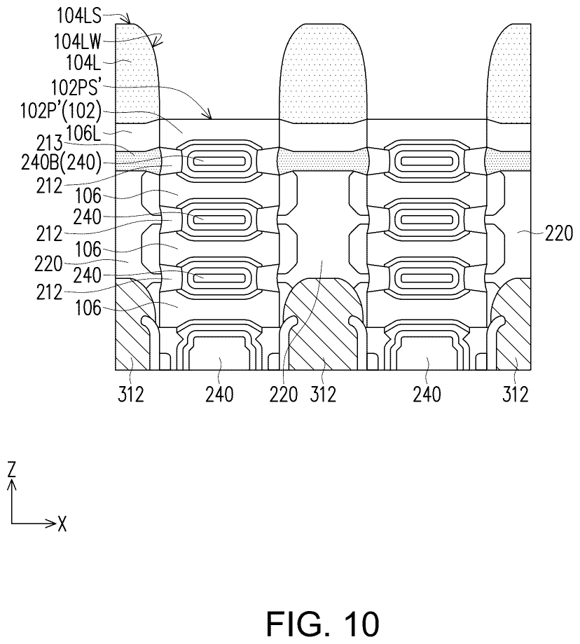

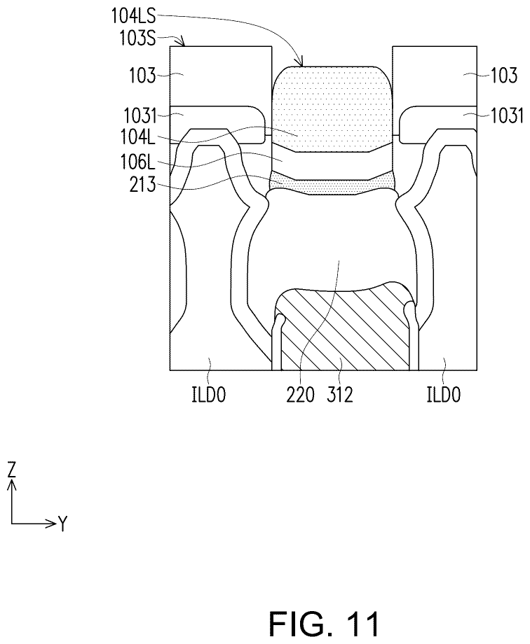

Referring to FIGS. 10-11 and with reference to FIGS. 8-9, the semiconductor substrate 102 may be partially removed by a selective etching process or other suitable removal process. In some embodiments, the etchant of the selective etching process is chosen so that a portion of the semiconductor substrate 102 is removed, while the first sacrificial portion 104L made of a different material than the semiconductor substrate 102 may remain substantially intact during the etching. For example, the base portion 102B and a part of the protrusions 102P connected to the base portion 102B are removed, leaving a portion of the protrusions 102P′ over the bottommost one 240B of the gate structures 240. In some embodiments, the protrusions 102P′ laterally cover the second sacrificial portion 106L. The back surface 104LS and the sidewalls 140LW of the first sacrificial portion 104L may be accessibly exposed by the protrusions 102P′. The back surface 102PS' of the respective protrusions 102P′ may be lower than the back surface 104LS of the adjacent first sacrificial portion 104L, relative to the bottommost one 240B of the gate structures 240. As shown in the Y-Z cross-section, the back surface 103S of the respective isolation structure 103 may be higher than the back surface 104LS of the adjacent first sacrificial portion 104L, relative to the epitaxial structure 220.

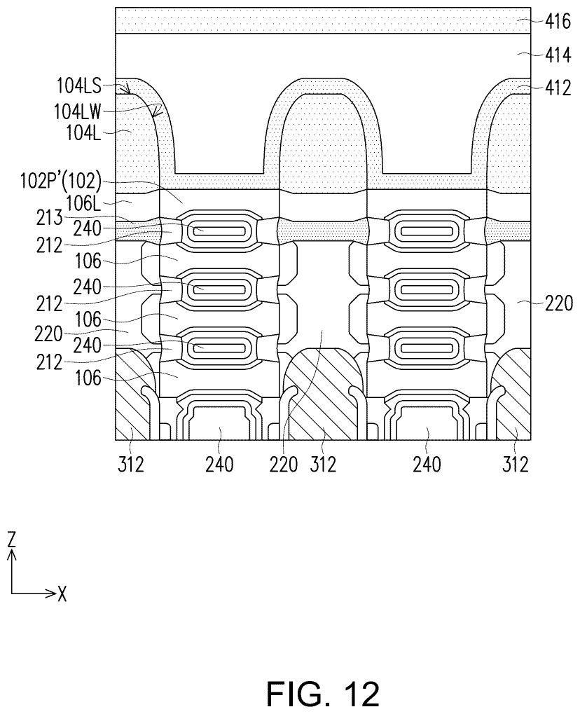

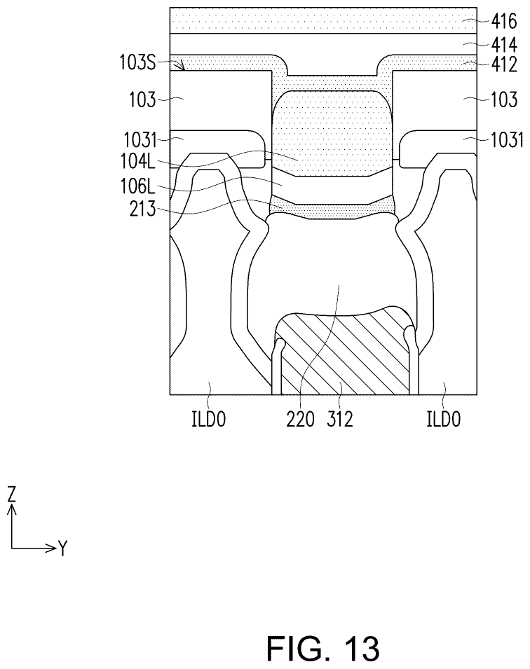

Referring to FIGS. 12-13 and with reference to FIGS. 10-11, a dielectric liner 412 may be conformally formed on the exposed surfaces of the first sacrificial portion 104L, the protrusions 102P′ of the semiconductor substrate 102, and the isolation structures 103. In some embodiments, the back surface 104LS and the sidewalls 140LW of the first sacrificial portion 104L, the back surface 102PS' of the respective protrusions 102P′, and the back surfaces 103S of the isolation structures 103 are lined with the dielectric liner 412. Next, a dielectric layer 414 and a hard mask layer 416 may be sequentially formed on the dielectric liner 412. In some embodiments, the hard mask layer 416 is or includes silicon oxynitride, silicon nitride, silicon carbide, silicon oxide, or a combination thereof, and may be formed by any suitable deposition process. The hard mask layer 416 may be formed of a different material than the underlying dielectric layer 414 and the dielectric liner 412. The dielectric liner 412 may be thinner than the overlying dielectric layer 414. In some embodiments, the dielectric liner 412 and the dielectric layer 414 are formed by different deposition processes. For example, the dielectric liner 412 is formed by atomic layer deposition (ALD), while the dielectric layer 414 is formed by chemical vapor deposition (CVD). Although other suitable deposition processes may be used to form the dielectric liner 412 and the dielectric layer 414. In some embodiments, a planarization process (e.g., CMP, grinding, combinations thereof, or the like) is performed on the dielectric layer 414 before the deposition of the hard mask layer 416.

In some embodiments, the dielectric liner 412 and the dielectric layer 414 are made of different materials. For example, the dielectric layer 414 is or includes silicon oxide, silicon carbide, silicon nitride, a combination thereof, etc. The material of the dielectric layer 414 may be selected to have a high etch selectivity to the dielectric liner 412 so that subsequent etching steps may be performed on the dielectric layer 414 without attacking the dielectric liner 412. For example, the dielectric liner 412 is made of an oxide, while the sacrificial isolation layer 213 is made of a nitride. In some embodiments, the dielectric liner 412 is made of a metal oxide (e.g., AlOx or the like), metal alloyed oxide, a combination thereof, and/or other suitable materials. In some embodiments, the dielectric liner 412 and the sacrificial isolation layer 213 are made of different materials so that subsequent etching steps may be performed on the sacrificial isolation layer 213 without attacking the dielectric liner 412.

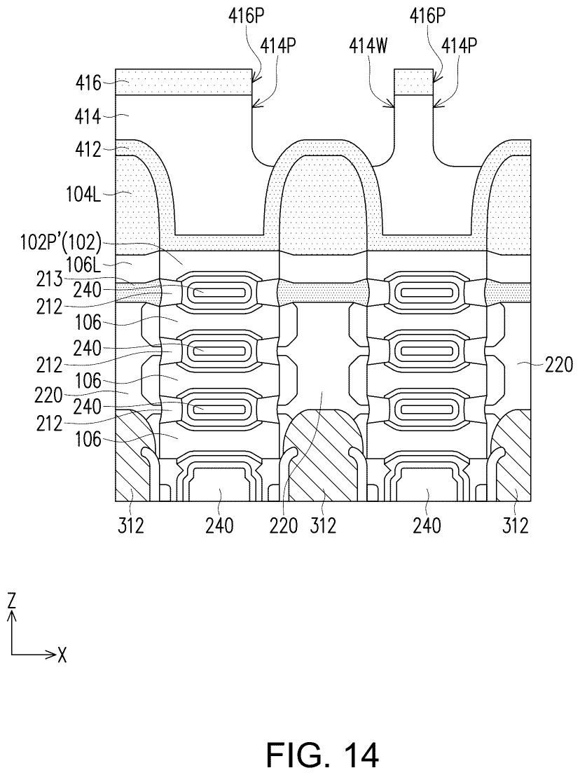

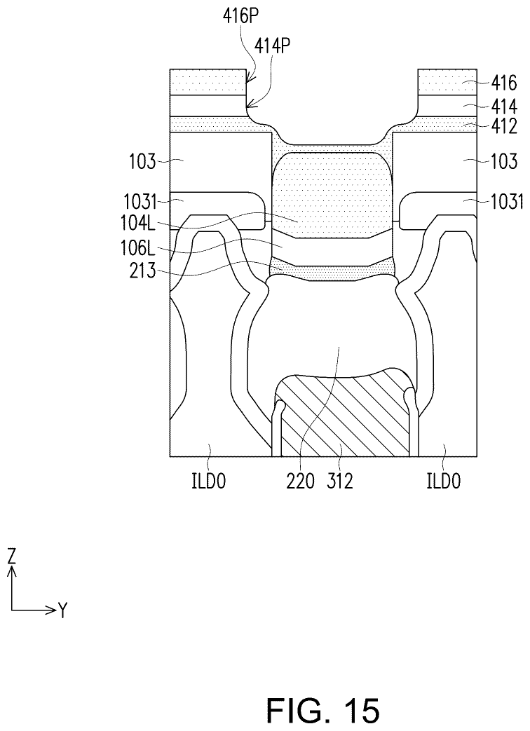

Referring to FIGS. 14-15 and with reference to FIGS. 12-13, the hard mask layer 416 may be patterned to form one or more opening(s) 416P, where the opening 416 exposes at least a portion of the dielectric layer 414. Next, the portion of the dielectric layer 414 exposed by the opening 416P may be removed to expose a portion of the dielectric liner 412. For example, an etching process is performed on the dielectric layer 414 to form the opening 414P. In some embodiments, the dielectric liner 412 serves as an etch stop during the etching. As shown in the X-Z cross-section, the inner sidewalls 414W of the dielectric layer 414 which define the openings 414P may be concaved curved at the bottom, since the first sacrificial portion 104L and the overlying dielectric liner 412 are protruded toward the dielectric layer 414. In some embodiments, during the etching (e.g., the formation of the openings 414P), the dielectric liner 412 is slightly etched as shown in the Y-Z cross-section. It should be noted that depending on the selected materials, the openings 414P of the dielectric layer 414 may have a different cross-sectional profile than shown.

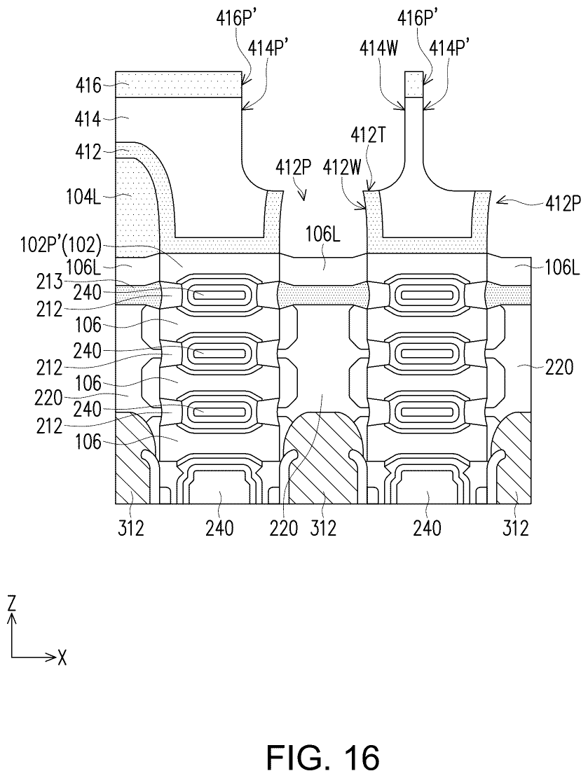

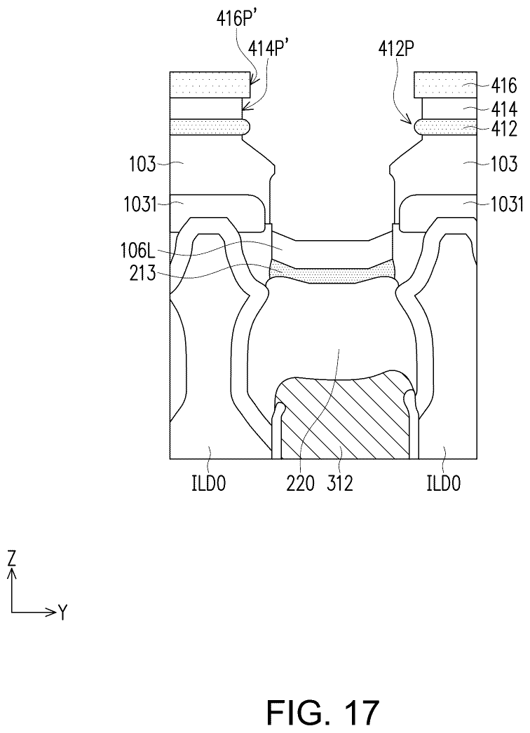

Referring to FIGS. 16-17 and with reference to FIGS. 14-15, a portion of the dielectric liner 412 exposed by the opening 414P and the first sacrificial portion 104L underlying the portion of the dielectric liner 412 may be removed to form the openings 412P. The openings 412P may be formed by chemical etch, plasma etch, and/or any suitable processing techniques. For example, the portion of the dielectric liner 412 and the first sacrificial portion 104L underlying the portion of the dielectric liner 412 are etched through the openings 414P and 416P. As shown in the X-Z cross-section, the top facets 412T and the inner sidewalls 412W of the dielectric liner 412 which define the opening 412P may be accessibly exposed, where the top facets 412T are connected to the inner sidewalls 412W of the dielectric liner 412 and the inner sidewalls 414W of the dielectric layer 414. In some embodiments, during the etching, the openings (414P and 416P) are laterally enlarged to form the openings 414P′ and 416P′, respectively. Since the etch rates of the dielectric liner 412, the dielectric layer 414, and the hard mask layer 416 are different, the etched sidewalls of the dielectric liner 412, the dielectric layer 414, and the hard mask layer 416 may not be aligned with one another as shown in the Y-Z cross-section. In some embodiments, when forming the openings 412P, the isolation structures 103 are slightly etched as shown in the Y-Z cross-section.

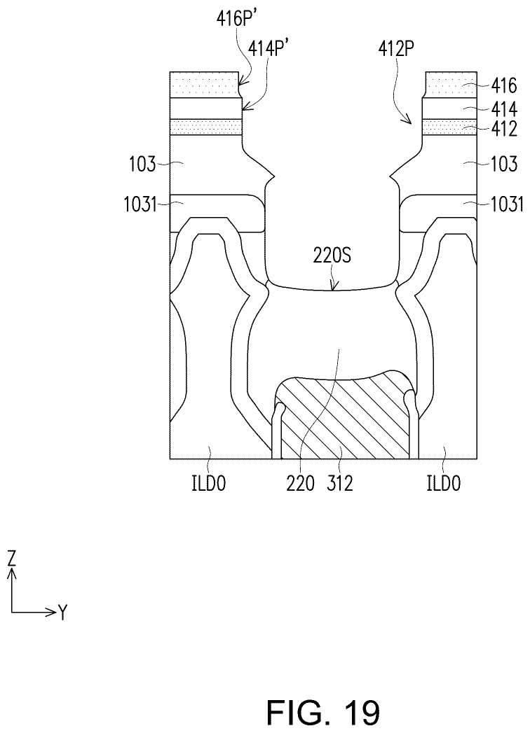

Referring to FIGS. 18-19 and with reference to FIGS. 16-17, the second sacrificial portion 106L exposed by the openings 412P and the sacrificial isolation layer 213 underlying the second sacrificial portion 106L may be removed to expose the bottom surfaces 220S of the epitaxial structures 220. In some embodiments where the second sacrificial portion 106L and the sacrificial isolation layer 213 are made of different materials, a two-step etching process is performed to remove the exposed second sacrificial portion 106L and the underlying sacrificial isolation layer 213. Since the dielectric liner 412 has a material different from the second sacrificial portion 106L and the sacrificial isolation layer 213, the dielectric liner 412 may remain substantially intact during the etching. In some embodiments, the dielectric liner 412 is more rigid than the dielectric layer 414. The dielectric liner 412 having a rigid material may be able to support the overlying dielectric layer 414 during the etching.

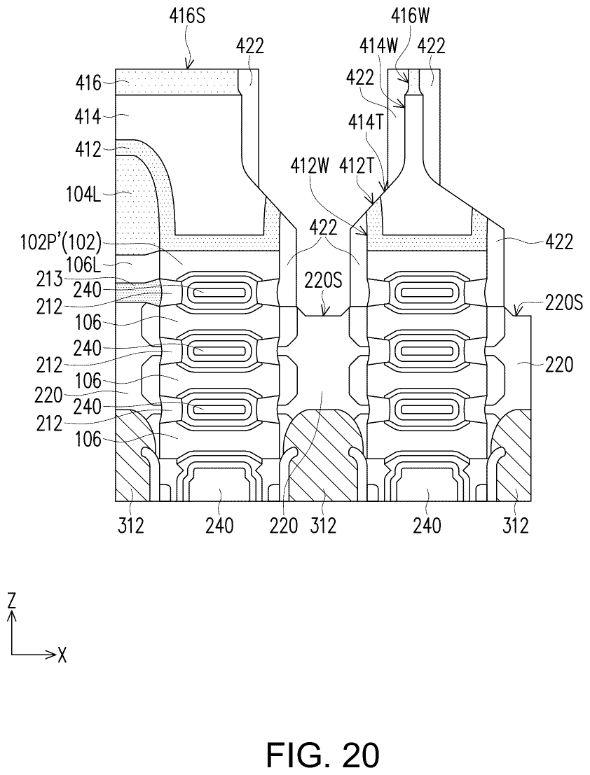

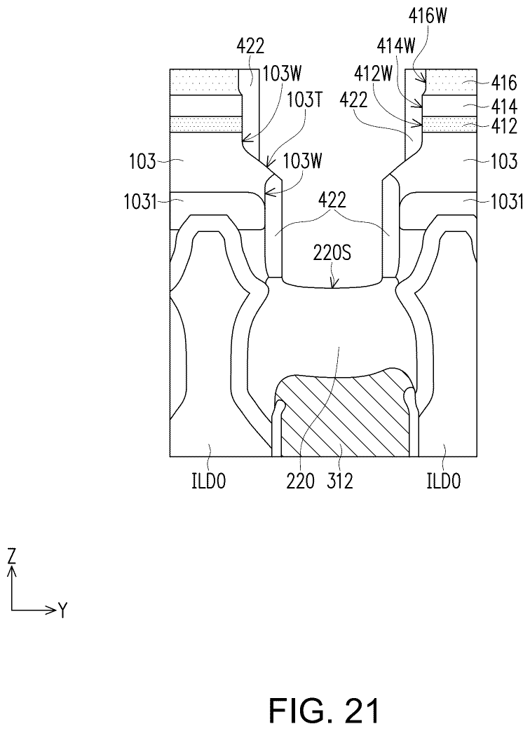

Referring to FIGS. 20-21 and with reference to FIGS. 18-19, a barrier liner 422 may be formed on the inner sidewalls 416W of the hard mask layer 416, the inner sidewalls 414W of the dielectric layer 414, and the inner sidewalls 412W of the dielectric liner 412. The barrier liner 422 may be or include silicon nitride, silicon carbon-nitride, silicon-carbon-oxynitride, or any other type of barrier materials. In some embodiments, the barrier liner 422 and the dielectric liner 412 are made of different materials. For example, the barrier liner 422 is a nitride, and the dielectric liner 412 is a metal oxide. In some embodiments, the barrier liner 422 and the dielectric layer 414 are made of different materials. For example, the barrier liner 422 is a nitride, and the dielectric layer 414 is an oxide. In some embodiments, the barrier liner 422 is formed by conformally depositing a barrier liner material on the hard mask layer 416 and in the openings (416P′, 414P′, and 412P); and performing an etch process to remove horizontal portions of the barrier liner material. For example, the bottom surfaces 220S of the epitaxial structures 220 and the bottom surface 416S of the hard mask layer 416 are exposed by the barrier liner 422. In some embodiments, the top facets 412T of the dielectric liner 412 and the bottom of the inner sidewalls 414W (e.g., the inclined facet 414T) connected to the top facets 412T are exposed by the barrier liner 422. As shown in the Y-Z cross-section, the inner sidewalls 103W of the respective isolation structure 103 may be partially covered by the barrier liner 422. For example, the inclined facets 103T of the inner sidewalls 103W are exposed by the barrier liner 422.

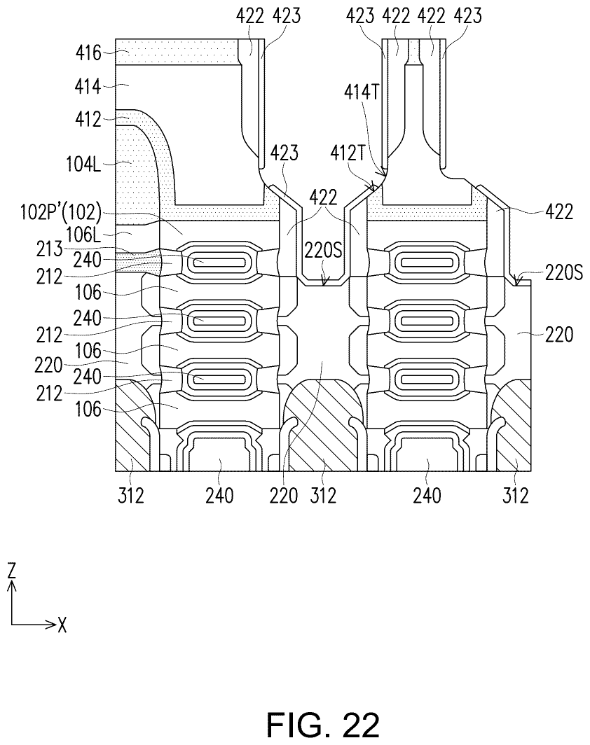

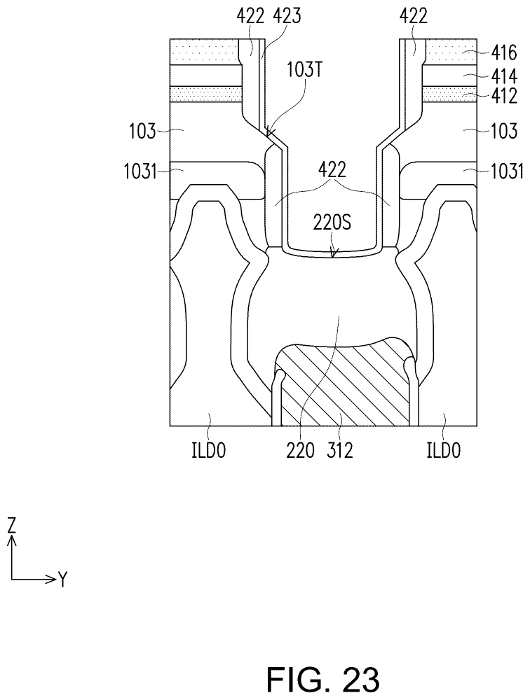

Referring to FIGS. 22-23 and with reference to FIGS. 20-21, a metallic liner 423 may be formed on the barrier liner 422 and the bottom surfaces 220S of the epitaxial structures 220. In some embodiments, before forming the metallic liner 423, a pre-cleaning process is performed to clean the via holes by using any suitable methods. For example, native oxides formed in the via holes are removed during the pre-cleaning process. The metallic liner 423 may be formed of TiN, titanium silicon nitride (TSN), and/or other suitable material, and may be formed by CVD, ALD, or any suitable deposition process. In some embodiments, the metallic liner 423 acts as an adhesion layer between the barrier liner 422 and the subsequently-formed filling-metal layer. In some embodiments, the metallic liner 423 extends further than the barrier liner 422 and may cover a portion of the inclined facet 414T of the dielectric layer 414 and/or the top facets 412T of the dielectric liner 412, as shown in the X-Z cross-section. Alternatively, the metallic liner 423 fully covers the inclined facet 414T of the dielectric layer 414 and the top facets 412T of the dielectric liner 412. In some embodiments, the inclined facets 103T of the isolation structures 103 may also be covered by the metallic liner 423 as shown in the Y-Z cross-section.

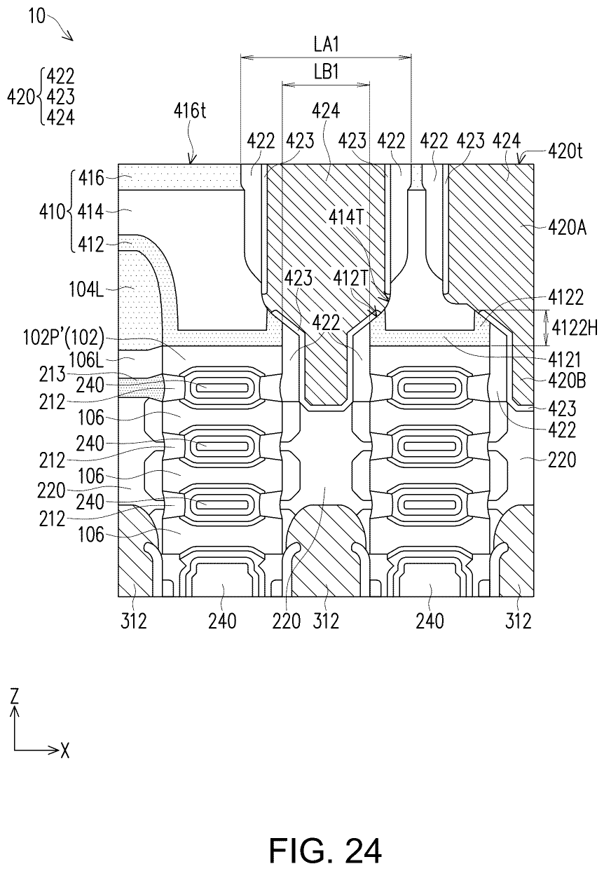

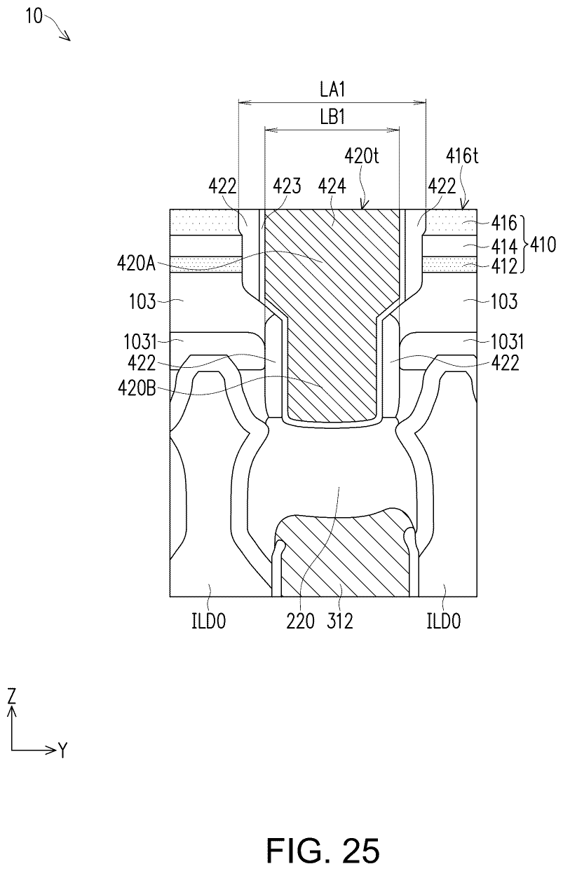

Referring to FIGS. 24-25 and with reference to FIGS. 22-23, a filling-metal layer 424 may be formed on the metallic liner 423 to fill the rest space of the via holes. In some embodiments, the filling-metal layer 424 is formed of tungsten, cobalt, and/or any suitable conductive material(s), which may be formed using ALD, CVD, or any suitable deposition process. In some embodiments, the filling-metal layer 424 is in direct contact with the inclined facet 414T of the dielectric layer 414 and the top facets 412T of the dielectric liner 412 which are exposed by the metallic liner 423, as shown in the X-Z cross-section. After the deposition of the filling-metal material, a planarization process (e.g., CMP, grinding, etching back, a combination thereof, etc.) may be performed to remove excess material, resulting in the backside vias 420. The hard mask layer 416 may serve as a stop layer during the planarization process. For example, the planarized surface 420t of the respective backside via 420 is substantially leveled (or coplanar) with the surface 416t of the hard mask layer 416, within process variations. The respective backside via 420 may include the barrier liner 422, the metallic liner 423, and the filling-metal layer 424. It should be noted that a portion of the semiconductor device 10 is shown herein; the subsequent backside routing process (not shown) may be performed on the backside of the semiconductor substrate according to the product and circuit design requirements.

With continued reference to FIGS. 24-25, the semiconductor device 10 may include the backside vias 420 electrically and vertically coupled to the epitaxial structures 220 (i.e. the S/D structures). The dielectric stack 410 of the semiconductor device 10 may include the dielectric liner 412, the dielectric layer 414, and the hard mask layer 416. For example, the dielectric stack 410 laterally surrounds the first portion 420A of the respective backside via 420. The second portion 420B of the respective backside via 420 connected to the first portion 420A may be connected to the epitaxial structures 220. In some embodiments, the respective backside via 420 has a wider first portion 420A and a narrower second portion 420B. For example, the lateral dimension LA1 of the first portion 420A is greater than the lateral dimension LB1 of the second portion 420B. In the X-Z cross-section, the second portion 420B of the respective backside via 420 may be laterally surrounded by the protrusions 102P′ of the semiconductor substrate 102 and the gate stack 240. In the Y-Z cross-section, the second portion 420B of the respective backside via 420 may be laterally surrounded by the isolation structures 103, the isolation hard mask 1031, and the ILD layer ILD0.

In the X-Z cross-section, the dielectric liner 412 of the dielectric stack 410 may have a U-shape profile having a horizontal portion 4121 and a sidewall portion 4122 connected to the horizontal portion 4121, where the horizontal portion 4121 is in physical contact with the underlying protrusion 102P′ of the semiconductor substrate 102, and the sidewall portion 4122 has one side in physical contact with the overlying dielectric layer 414 and the opposing side in physical contact with the backside via 420. The horizontal portion 4121 of the dielectric liner 412 may protect the protrusion 102P′ of the semiconductor substrate 102, so that the protrusion 102P′ may remain a sufficient thickness without being etched when forming the via holes for the backside vias 420 (e.g., the processes of FIGS. 16-19). The protrusion 102P′ of the semiconductor substrate 102 having a sufficient thickness may reduce the risk of current leakage, thereby improving the resulting device performance and yield.

The cross-sectional profile (see FIG. 24) of the dielectric liner 412 may become a receptacle of the dielectric layer 414. For example, the sidewall portion 4122 has a maximum height 4122H which is in a range of about 3 μm and about 20 μm. The material of the dielectric liner 412 is selected such that the dielectric liner 412 may serve as a receptacle (or a support) of the dielectric layer 414 during forming the via holes for the backside vias 420 (e.g., the processes of FIGS. 16-19). As the demand for larger critical dimension of the backside vias and shorter backside vias in order to achieve Rc reduction has grown, the dielectric stack 410 including the dielectric liner 412 serving as a support for the overlying dielectric layer 414 may enable the formation of the larger via holes (see FIGS. 18-19) for the backside vias 420. In this manner, even if the critical dimension of the backside vias is enlarged, the dielectric stack 410 including the dielectric liner 412 may serve as isolation between adjacent backside vias 420 to reduce the bridge risk therebetween, thereby reducing AC penalty and improving performance of the semiconductor device 10.

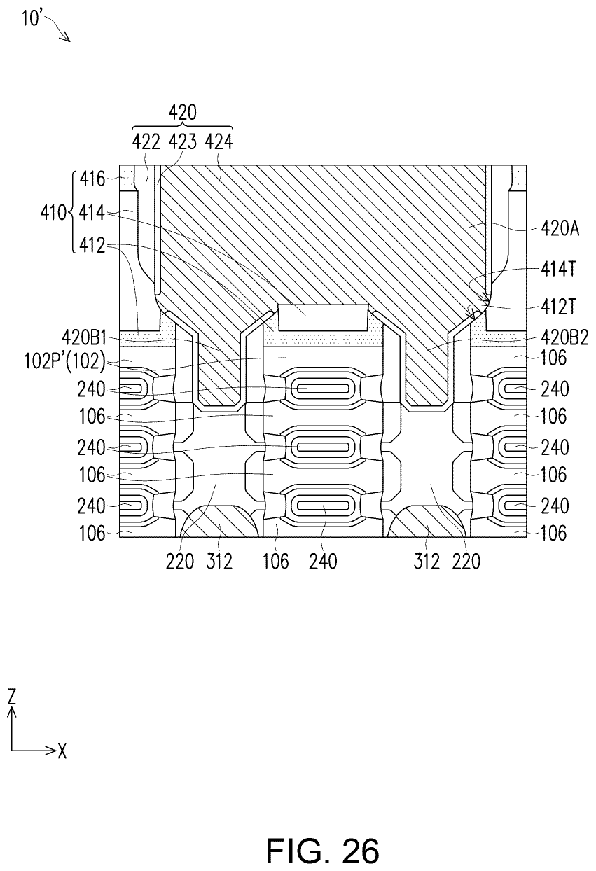

FIG. 26 is a schematic cross-sectional view illustrating a portion of a semiconductor device, in accordance with some embodiments. Unless specified otherwise, like reference numerals represent like components in the embodiment shown in FIGS. 8-25. Referring to FIG. 26 and FIG. 24, the structure of the semiconductor device 10′ shown in FIG. 26 is similar to the structure of the semiconductor device 10 shown in FIG. 24, the difference therebetween includes that the upper portions 420A of the adjacent backside vias 420 are merged together. Such a profile not only enlarges a landing window for another conductive feature formed on the backside vias 420, but it also enhances an electrical isolation or separation between the backside vias 420 and the gate structures 240, which may help prevent undesirable electrical failure.

The present disclosure optimizes an X-cut profile of the backside vias 420 by forming the dielectric stack 410 including the dielectric liner 412, where the dielectric liner 412 may act as a receptacle of the overlying dielectric layer 414. For example, a combination of the dielectric liner 412 and the dielectric layer 414 separates the lower portion 420B1 on the left hand side from the lower portion 420B2 on the right hand side, as shown in FIG. 26. The dielectric liner 412 may also protect the underlying protrusions 102P′ of the semiconductor substrate 102 from being etched and may ensure proper thickness of the underlying protrusions 102P′ of the semiconductor substrate 102. The lower corners of the upper portion 420A in the X-Z cross-section may have a rounded cross-sectional shape. For example, the lower corners of the upper portion 420A in the X-Z cross-section have a concave curved surface. The top facets 412T of the dielectric liner 412 and the inclined facet 414T of the dielectric layer 414 may be in direct contact with the lower corners of the upper portion 420A of the backside vias 420. This may allow enough process window and sufficient isolation between the backside vias 420 and the gate structures 240, thereby reducing AC penalty and improving device performance.

According to some embodiments, a semiconductor device includes a semiconductor substrate including a first side and a second side opposite to each other, semiconductor channel layers disposed over the first side of the semiconductor substrate and vertically separating apart from one another, a gate structure vertically between adjacent two of the semiconductor channel layers, a source/drain (S/D) structure laterally abutting the semiconductor channel layers, a dielectric stack including a dielectric liner connecting the second side of the semiconductor substrate and a dielectric layer overlying the dielectric liner and having a different material than the dielectric liner, and a backside via landing on the S/D structure and laterally surrounded by the dielectric stack.

According to some embodiments, a semiconductor device includes a semiconductor substrate including a first side and a second side opposite to each other, gate structures and semiconductor channel layers vertically and alternately stacked upon one another over the first side of the semiconductor substrate, a S/D structure laterally connecting the semiconductor channel layers and separating from the gate structures, a dielectric liner covering the second side of the semiconductor substrate, a dielectric layer overlying the dielectric liner, wherein the dielectric liner acts as a receptacle of the dielectric layer, and a backside via connected to the S/D structure and laterally surrounded by the dielectric liner and the dielectric layer.

According to some embodiments, a manufacturing method of a semiconductor device includes: forming semiconductor channel layers, gate structures, and a S/D structure on a first side of a semiconductor substrate, where the gate structures and the semiconductor channel layers are vertically and alternately stacked upon one another and over the semiconductor substrate, and the S/D structure is laterally connected to the semiconductor channel layers, and a first sacrificial semiconductor portion, a second sacrificial semiconductor portion, and a sacrificial isolation layer are sequentially stacked, and the sacrificial isolation layer is connected to the S/D structure; forming a dielectric liner and a dielectric layer overlying the dielectric liner, where the semiconductor substrate and the first sacrificial semiconductor portion are lined with the dielectric liner, and the dielectric liner and the dielectric layer have an opening exposing a portion of the first sacrificial semiconductor portion; removing the first sacrificial semiconductor portion, the second sacrificial semiconductor portion, and the sacrificial isolation layer through the opening to expose the S/D structure; and forming a backside via in the opening to land on the S/D structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate comprising a first side and a second side opposite to each other;
semiconductor channel layers disposed over the first side of the semiconductor substrate and vertically separating apart from one another;
a gate structure vertically between adjacent two of the semiconductor channel layers;
a source/drain (S/D) structure laterally abutting the semiconductor channel layers;
a dielectric stack comprising a dielectric liner connecting the second side of the semiconductor substrate and a dielectric layer overlying the dielectric liner and having a different material than the dielectric liner; and
a backside via landing on the S/D structure and laterally surrounded by the dielectric stack.

2. The semiconductor device of claim 1, wherein in a cross-sectional view, the dielectric liner has a U-shape profile and accommodates the dielectric layer therein.

3. The semiconductor device of claim 1, wherein the dielectric liner is more rigid than the dielectric layer.

4. The semiconductor device of claim 1, wherein the backside via comprising a first portion laterally surrounded by the dielectric stack and a second portion between the first portion and the S/D structure and narrower than the first portion, and the second portion laterally abuts the semiconductor substrate.

5. The semiconductor device of claim 4, wherein the first portion of the backside via has a rounded corner which is near the second portion and is in contact with facets of the dielectric liner and the dielectric layer.

6. The semiconductor device of claim 1, further comprising:
inner spacers disposed on opposite sidewalls of the gate structure, the inner spacers being in lateral contact with the backside via.

7. The semiconductor device of claim 1, wherein the backside via comprising a barrier liner, a metallic liner on the barrier liner, and a filling-metal layer on the metallic liner, wherein the barrier liner separates the metallic liner from the dielectric layer, the dielectric liner, and the semiconductor substrate.

8. The semiconductor device of claim 7, wherein the filling-metal layer of the backside via is in contact with the dielectric liner and the dielectric layer.

9. The semiconductor device of claim 7, wherein the metallic liner is in partial contact with the dielectric layer and the dielectric liner.

10. The semiconductor device of claim 7, wherein the metallic liner is in contact with the S/D structure.

11. A semiconductor device, comprising:
a semiconductor substrate comprising a first side and a second side opposite to each other;
gate structures and semiconductor channel layers vertically and alternately stacked upon one another over the first side of the semiconductor substrate;
a S/D structure laterally connecting the semiconductor channel layers and separating from the gate structures;
a dielectric liner covering the second side of the semiconductor substrate;
a dielectric layer overlying the dielectric liner, wherein the dielectric liner acts as a receptacle of the dielectric layer; and
a backside via connected to the S/D structure and laterally surrounded by the dielectric liner and the dielectric layer.

12. The semiconductor device of claim 11, wherein the backside via comprises a wider portion laterally covered by the dielectric layer and a narrower portion connected to the wider portion and landing on the S/D structure.

13. The semiconductor device of claim 12, wherein the dielectric liner is connected to an intersection of the wider portion and the narrower portion.

14. The semiconductor device of claim 13, wherein the intersection of the wider portion and the narrower portion comprises a concave curved profile in a cross-sectional view.

15. The semiconductor device of claim 11, wherein the dielectric liner is thinner than the dielectric layer and is made of a different material than the dielectric layer.

16. A method of forming a semiconductor device, comprising:
forming semiconductor channel layers, gate structures, and a S/D structure on a first side of a semiconductor substrate, wherein:
the gate structures and the semiconductor channel layers are vertically and alternately stacked upon one another and over the semiconductor substrate, and the S/D structure is laterally connected to the semiconductor channel layers,
a first sacrificial semiconductor portion, a second sacrificial semiconductor portion, and a sacrificial isolation layer are sequentially stacked, and the sacrificial isolation layer is connected to the S/D structure;
forming a dielectric liner and a dielectric layer overlying the dielectric liner, wherein the semiconductor substrate and the first sacrificial semiconductor portion are lined with the dielectric liner, and the dielectric liner and the dielectric layer have an opening exposing a portion of the first sacrificial semiconductor portion;
removing the first sacrificial semiconductor portion, the second sacrificial semiconductor portion, and the sacrificial isolation layer through the opening to expose the S/D structure; and
forming a backside via in the opening to land on the S/D structure.

17. The method of claim 16, wherein the second sacrificial semiconductor portion is laterally connected to the semiconductor substrate and has a material same as the semiconductor substrate, and the first sacrificial semiconductor portion has a different material than the second sacrificial semiconductor portion.

18. The method of claim 16, wherein the dielectric liner has a different material than the sacrificial isolation layer and the dielectric layer.

19. The method of claim 16, wherein forming the dielectric liner and the dielectric layer comprises:
conformally depositing a liner material on the semiconductor substrate and the first sacrificial semiconductor portion;
depositing a dielectric material on the liner material;
etching the dielectric material to expose a portion of the liner material overlying the first sacrificial semiconductor portion; and
etching the portion of the liner material to expose the portion of the first sacrificial semiconductor portion.

20. The method of claim 16, wherein after removing the first sacrificial semiconductor portion, the opening of the dielectric liner and the dielectric layer is enlarged.
